(19) United States
(12) Patent Application Publication
(10) Pub. No.: US 2022/0076897 A1
(43) Pub. Date: Mar. 10, 2022

(54) PEROVSKITE SOLAR CELL AND METHOD OF MANUFACTURING THE SAME

(71) Applicant: ELECTRONICS AND TELECOMMUNICATIONS RESEARCH INSTITUTE, Daejeon (KR)

(72) Inventors: Ga Young KIM, Daejeon (KR); JungWook LIM, Daejeon (KR)

(73) Assignee: ELECTRONICS AND TELECOMMUNICATIONS RESEARCH INSTITUTE, Daejeon (KR)

(21) Appl. No.: 17/373,273

(22) Filed: Jul. 12, 2021

(30) Foreign Application Priority Data
Sep. 7, 2020 (KR) 10-2020-0113712
Dec. 9, 2020 (KR) 10-2020-0171082

(51) Int. Cl. H01G 9/20; H01L 51/42; H01L 51/00

(52) U.S. Cl. CPC H01G 9/2009; H01L 51/4213; H01L 51/0021; H01G 9/204; H01G 9/2027; H01G 9/2031

(57) ABSTRACT

Provided is a perovskite solar cell including a substrate, a lower transparent electrode provided on the substrate, an upper transparent electrode provided on the lower transparent electrode, and a light absorption layer interposed between the lower transparent electrode and the upper transparent electrode, wherein the light absorption layer includes a perovskite material, and at least one of the lower transparent electrode or the upper transparent electrode includes a first color implementation layer, an intermediate layer, and a second color implementation layer, which are sequentially stacked, the first color implementation layer and the second color implementation layer each being a metal oxide layer containing a dopant.

### CROSS-REFERENCE TO RELATED APPLICATIONS

This U.S. non-provisional patent application claims priority under 35 U.S.C. § 119 of Korean Patent Application Nos. 10-2020-0113712, filed on Sep. 7, 2020, and 10-2020-0171082, filed on Dec. 9, 2020, the entire contents of which are hereby incorporated by reference.

### BACKGROUND

The present disclosure herein relates to a perovskite solar cell, and more particularly, to a perovskite solar cell module including a multilayer transparent electrode.

Solar cells serve as a means of converting solar energy into electrical energy, and thus, use a photoelectric effect to generate electric power. Among such solar cells, a perovskite solar cell is drawing great attention in that the cell requires low manufacturing cost, may possibly be manufactured as a thin film through a wet process, and has superior photoelectric conversion efficiency to existing solar cells.

Currently, the solar cell is typically represented by a crystalline silicon-based solar cell, and a BIPV system in which solar cells are integrated in urban buildings to produce electricity is being actively researched and developed. In the BIPV system, what matters is to secure a sufficiently high amount of power generation without spoiling aesthetic features, and to inevitably display a wide range of colors to meet the needs of aesthetic values.

### SUMMARY

The present disclosure provides a perovskite solar cell module capable of displaying various colors.

The present disclosure is not limited to the technical aspects described above, and those skilled in the art may understand other technical aspects from the following description.

An embodiment of the inventive concept provides a perovskite solar cell including a substrate, a lower transparent electrode provided on the substrate, an upper transparent electrode provided on the lower transparent electrode, and a light absorption layer interposed between the lower transparent electrode and the upper transparent electrode, wherein the light absorption layer includes a perovskite material, and at least one of the lower transparent electrode or the upper transparent electrode includes a first color implementation layer, an intermediate layer, and a second color implementation layer, which are sequentially stacked, the first color implementation layer and the second color implementation layer each being a metal oxide layer containing a dopant.

In an embodiment, the intermediate layer may contain silver (Ag), gold (Au), aluminum (Al), copper (Cu), titanium (Ti), platinum (Pt), tungsten (W), nickel (Ni), and/or titanium nitride (TiN).

In an embodiment, the dopant may contain boron (B), aluminum (Al), gallium (Ga), indium (In), a lanthanide element, and/or titanium (Ti).

In an embodiment, the metal oxide may contain ZnO, TiO₂, SnO₂, In₂O₃, ITO, ATO (antimony tin oxide), WOₓ, and/or MoOₓ.

In an embodiment, the intermediate layer may have a thickness of about 1 nm to about 15 nm.

In an embodiment, the lower transparent electrode and the upper transparent electrode each may have a thickness of about 10 nm to about 200 nm.

In an embodiment, the light absorption layer may be opaque.

In an embodiment, the first color implementation layer may have the same refractive index as the second color implementation layer.

In an embodiment of the inventive concept, a method of manufacturing a perovskite solar cell includes forming a lower transparent electrode on a substrate, and forming a light absorption layer on the lower transparent electrode, wherein the forming of the lower transparent electrode includes sequentially forming a first color implementation layer, an intermediate layer, and a second color implementation layer on the substrate, and the forming of the first color implementation layer includes performing a first sub-cycle n times and performing a second sub-cycle m times, the first sub-cycle including supplying a first precursor into a chamber in which the substrate is prepared, supplying a first inert gas into the chamber to perform a first purge process, supplying a first reaction gas into the chamber, and supplying a second inert gas into the chamber to perform a second purge process.

In an embodiment, n above may be a natural number of 1 to 10, and m above may be a natural number of 1 to 100.

In an embodiment, the second sub-cycle may include supplying a second precursor into the chamber, supplying a third inert gas into the chamber to perform a third purge process, supplying a second reaction gas into the chamber, and supplying a fourth inert gas into the chamber to perform a fourth purge process, wherein the second precursor may contain a different material from the first precursor.

In an embodiment, the first color implementation layer and the second color implementation layer each may be a metal oxide layer containing a dopant, and the intermediate layer may contain silver (Ag), gold (Au), aluminum (Al), copper (Cu), titanium (Ti), platinum (Pt), tungsten (W), nickel (Ni), and/or titanium nitride (TiN).

In an embodiment, the light absorption layer may include a perovskite material.

In an embodiment, the forming of the second color implementation layer may include, on the intermediate layer, performing the first sub-cycle x times and performing the second sub-cycle y times, wherein n above may be different from x above, and m above may be different from y above.

In an embodiment, the method may further include forming an upper transparent electrode on the light absorption layer, wherein the forming of the upper transparent electrode may include, on the light absorption layer, sequentially forming a third color implementation layer, an intermediate layer, and a fourth color implementation layer, and the forming of the third color implementation layer may include, on the light absorption layer, performing the first sub-cycle a times and the second sub-cycle b times.

In an embodiment, the forming of the fourth color implementation layer may include, on the intermediate layer, performing the first sub-cycle c times and performing the second sub-cycle d times, wherein a above may be different from c above, and b above may be different from d above.

In an embodiment, the greater a ratio of the number of times n of performing the first sub-cycle to the number of times m of performing the second sub-cycle, the less a refractive index of the lower transparent electrode.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a cross-sectional view of a perovskite solar cell according to an embodiment of the inventive concept;

FIG. 2 is a cross-sectional view of a perovskite solar cell according to another embodiment of the inventive concept;

FIG. 3 is a cross-sectional view of a perovskite solar cell according to another embodiment of the inventive concept;

FIG. 4 is a conceptual view of a process for forming a first color implementation layer according to an embodiment of the inventive concept; and

FIG. 5 is a graph showing a change in refractive index of a lower transparent electrode according to an embodiment of the inventive concept.

### DETAILED DESCRIPTION

In order to fully understand the configuration and effects of the inventive concept, preferred embodiments of the inventive concept will be described in more detail with reference to the accompanying drawings.

The inventive concept may be embodied in different forms and variously modified and changed, and should not be constructed as limited to the embodiments set forth herein. Rather, these embodiments are provided so that this disclosure will be thorough and complete, and will fully convey the scope of the inventive concept to those skilled in the art. In the drawings, the sizes of respective elements are exaggerated for convenience of description, and the ratios of respective elements may be exaggerated or reduced.

The terminology used herein is not for delimiting the embodiments of the inventive concept but for describing the embodiments. In addition, unless otherwise defined, all terms used herein have the same meaning as commonly understood by one of ordinary skill in the art to which this disclosure pertains.

In the present description, the terms of a singular form may include plural forms unless otherwise specified. It will be further understood that the terms “comprise” and/or “comprising”, when used in this description, specify the presence of stated elements, steps, operations, and/or components, but do not preclude the presence or addition of one or more other elements, steps, operations, and/or components.

In the present description, it will be understood that when a layer is referred to as being ‘on’ another layer, it can be formed directly on an upper surface of another layer, or a third layer may be interposed therebetween.

Though terms like a first, and a second are used to describe various regions and layers in the present description, the regions and the layers are not limited to these terms. These terms are used only to tell one region or layer from another region or layer. Therefore, a portion referred to as a first portion in one embodiment may be referred to as a second portion in another embodiment. An embodiment described and exemplified herein includes a complementary embodiment thereof. Like reference numerals refer to like elements throughout.

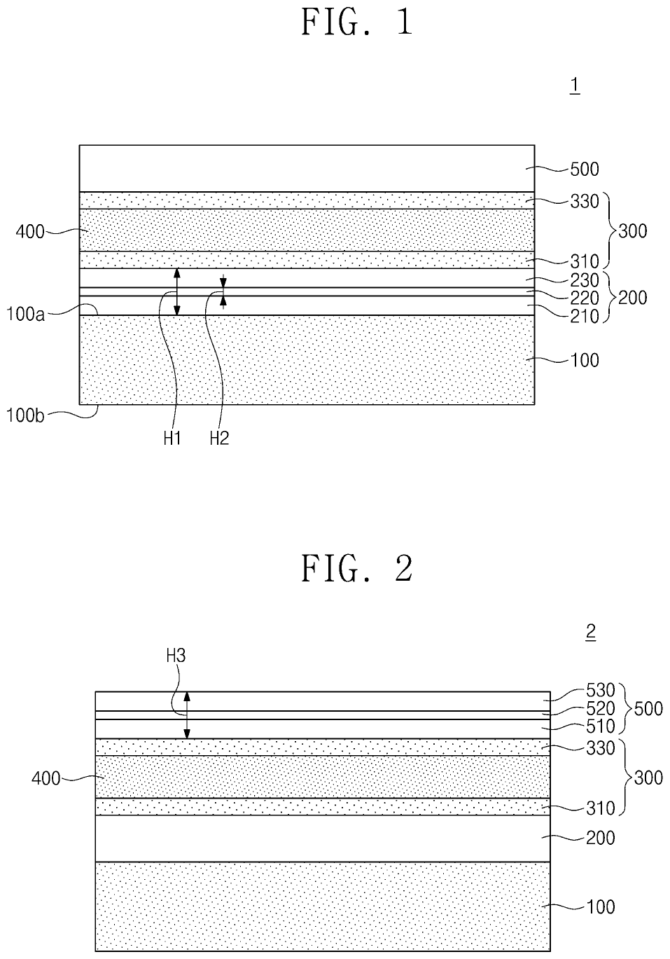

FIG. 1 is a cross-sectional view of a perovskite solar cell according to an embodiment of the inventive concept.

Referring to FIG. 1, a perovskite solar cell 1 according to embodiments of the inventive concept may include a substrate 100, a lower transparent electrode 200, an electron/hole transport layer 300, an absorption layer 400, and an upper transparent electrode 500. The lower transparent electrode 200 may include a first color implementation layer 210, an intermediate layer 220, and a second color implementation layer 230.

The substrate 100 may be a transparent substrate. For example, the substrate 100 may include transparent glass or a transparent polymer material. For example, the substrate 100 may be glass, sapphire, polyimide (PI), polyethylene terephthalate (PET), polyethylenenaphthalate (PEN), polyether sulfone (PES), or an acrylic material. The substrate 100 may include a first surface and a second surface facing each other. Solar light may be incident from the outside towards the first surface 100a.

The lower transparent electrode 200 may be provided on the first surface 100a of the substrate 100. The lower transparent electrode 200 may have a multilayer structure including a first color implementation layer 210, an intermediate layer 220, and a second color implementation layer 230, which are sequentially stacked. The lower transparent electrode 200 may have a thickness H1 of about 10 nm to about 200 nm. Electrons or holes generated by a photoelectric effect may flow through the lower transparent electrode 200.

The first color implementation layer 210 may include a transparent conductive material. To be more specific, the first color implementation layer 210 may include a metal oxide and dopant impurities. In an embodiment, the metal oxide may contain ZnO, TiO₂, SnO₂, In₂O₃, ITO, ATO (antimony tin oxide), WOₓ, and/or MoOₓ. The dopant impurities, for example, may contain boron (B), aluminum (Al), gallium (Ga), indium (In), a lanthanide element, and/or titanium (Ti). However, materials constituting the first color implementation layer 210 may not be limited thereto. The first color implementation layer 210 includes dopant impurities and may thus have a lower resistance. Accordingly, the lower transparent electrode 200 may have improved electrical conductivity.

The second color implementation layer 230 may include a transparent conductive material. The second color implementation layer 230 may include a material which is the same as or different from the first color implementation layer 210. For example, the second color implementation layer 230 may include ZnO, TiO₂, SnO₂, In₂O₃, ITO, ATO (antimony tin oxide), WOₓ, and/or MoOₓ. The second color implementation layer 230 may include dopant impurities. The dopant impurities, for example, may contain boron (B), aluminum (Al), gallium (Ga), indium (In), a lanthanide element, and/or titanium (Ti). However, materials constituting the second color implementation layer 230 may not be limited thereto. The second color implementation layer 230 includes dopant impurities and may thus have a lower resistance. Accordingly, the lower transparent electrode 200 may have improved electrical conductivity. In addition, the second color implementation layer 230 may replace the role of a first electron/hole transport layer 310. In this case, a separate electron/hole transport layer is not required, resulting in a simpler structure and increased efficiency.

Each of the first color implementation layer 210 and the second color implementation layer 230 may have a different refractive index according to the amount of dopant impurities. Accordingly, the refractive index and solar reflectance of the lower transparent electrode 200 may vary.

The intermediate layer 220 may be interposed between the first color implementation layer 210 and the second color implementation layer 230. The intermediate layer 220 may be a metal thin film layer or a metal nitride thin film layer. The intermediate layer 220 may include a metal material, for example, silver (Ag), gold (Au), aluminum (Al), copper (Cu), titanium (Ti), platinum (Pt), tungsten (W), and/or nickel (Ni). The intermediate layer 220 includes a metal material, and may thus improve electrical conductivity of the lower transparent electrode 200. For another example, the intermediate layer 220 may include a metal nitride such as titanium nitride (TiN). The intermediate layer 220 may have a predetermined thickness through which solar light may be transmitted. For example, the intermediate layer 220 may have a thickness H2 of about 1 nm to about 15 nm. According to the thickness and material of the intermediate layer 220, brightness and chroma of reflected light of the perovskite solar cell according to an embodiment may vary. Accordingly, a perovskite solar cell that displays a wide range of colors may be provided by varying the thickness and material type of the intermediate layer 220.

The electron/hole transport layer 300 may be provided on the lower transparent electrode 200. The electron/hole transport layer 300 may include first and second electron/hole transport layers 310 and 330. More specifically, the first electron/hole transport layer 310 may be provided on an upper surface of the lower transparent electrode 200. The first electron/hole transport layer 310 may directly contact the second color implementation layer 230 of the lower transparent electrode 200. The first electron/hole transport layer 310 may include a material having an energy band capable of moving electrons or holes. The first electron/hole transport layer 310 may include a polymer material, a monomolecular material, or a metal oxide. For example, the electron transport layer 120 may include TiO₂, a fullerene derivative (e.g., PCBM), or PEDOT:PSS, but is not limited thereto.

The second electron/hole transport layer 330 may be provided on the first electron/hole transport layer 310. The second electron/hole transport layer 330 may include a material which is the same as or different from the first electron/hole transport layer 310. For example, the second electron/hole transport layer 330 may include a polymer material, a monomolecular material, or a metal oxide. For example, the electron transport layer 120 may include TiO₂, a fullerene derivative (e.g., PCBM), or PEDOT:PSS, but is not limited thereto.

The light absorption layer 400 may be interposed between the first electron/hole transport layer 310 and the second electron/hole transport layer 330. The light absorption layer 400 may absorb solar light. The light absorption layer 400 may include a perovskite material. For example, the light absorption layer 130 may include an organic/inorganic composite perovskite material. The perovskite material of the light absorption layer 400 may have a crystal structure with the AMX₃ formula. For example, A may include an organic cationic material, M may include a metal cationic material, and X may include a halogen anionic material, but materials constituting the light absorption layer 130 are not limited thereto.

The light absorption layer 400 may absorb solar light to generate electron-hole pairs (photoelectric effect). Electrons generated from the light absorption layer 400 may move to any one of the first electron/hole transport layer 310 or the second electron/hole transport layer 330, and holes generated from the light absorption layer 400 may move to the other one of the first electron/hole transport layer 310 or the second electron/hole transport layer 330. The perovskite material has a high light absorption coefficient, and thus is excellent in light absorption, and is capable of generating electron-hole pairs even at low energy due to low exciton binding energy. In addition, electrons and holes have a long diffusion distance, and the solar cell may thus have increased efficiency.

The upper transparent electrode 500 may be provided on the second electron/hole transport layer 330. The upper transparent electrode 500 may be a single layer. The upper transparent electrode 500 may include a material which is the same as or different from the first color implementation layer 210 or the second color implementation layer 230. The transparent electrode 500 may include a transparent conductive material. More specifically, the upper transparent electrode 500 may include a metal oxide. For example, the upper transparent electrode 500 may include ZnO, TiO₂, SnO₂, In₂O₃, ITO, ATO (antimony tin oxide), WOₓ, and/or MoOₓ. The lower transparent electrode 500 may include dopant impurities. The dopant impurities, for example, may contain boron (B), aluminum (Al), gallium (Ga), indium (In), a lanthanide element, and/or titanium (Ti). However, materials constituting the upper transparent electrode 500 may not be limited thereto. Solar light may be incident from the outside towards the light absorption layer 400 through the upper transparent electrode 500, and electrons or holes generated by the photoelectric effect may flow through the upper transparent electrode 500. In addition, the third color implementation layer 510 may replace the role of the second electron/hole transport layer 330, and in this case, a separate electron/hole transport layer is not required, resulting in a simpler structure and improved efficiency.

According to an embodiment of the inventive concept, the lower transparent electrode 200 may be a multilayer including first and second color implementation layers 210 and 230 and an intermediate layer 220, and the upper transparent electrode 500 may be a single layer. The refractive index of the lower transparent electrode 200 may vary according to the amount of dopant impurities in the first and second color implementation layers 210 and 230, and brightness and chroma of solar light reflected from the lower transparent electrode 200 may vary according to the thickness and material type of the intermediate layer 220.

FIG. 2 is a cross-sectional view of a perovskite solar cell according to another embodiment of the inventive concept. Detailed descriptions of technical features that overlap those described with reference to FIG. 1 will be omitted, and differences will be described in more detail.

Referring to FIG. 2, a perovskite solar cell 2 according to another embodiment of the inventive concept may include a substrate 100, a lower transparent electrode 200, an electron/hole transport layer 300, an absorption layer 400, and an upper transparent electrode 500. The substrate 100, the electron/hole transport layer 300, and the absorption layer 400 may be substantially the same as those described with reference to FIG. 1.

The lower transparent electrode 200 may be provided on a first surface 100a of the substrate 100. The lower transparent electrode 200 may be a single layer. The lower transparent electrode 200 may include a material which is the same as or different from the first color implementation layer 210 or the second color implementation layer 230 described in FIG. 1. The lower transparent electrode 200 may include a transparent conductive material. More specifically, the lower transparent electrode 200 may include a metal oxide. For example, the lower transparent electrode 200 may include ZnO, TiO₂, SnO₂, In₂O₃, ITO, ATO (antimony tin oxide), WOₓ, and/or MoOₓ. The lower transparent electrode 200 may further include dopant impurities. The dopant impurities, for example, may contain boron (B), aluminum (Al), gallium (Ga), indium (In), a lanthanide element, and/or titanium (Ti). However, materials constituting the lower transparent electrode 200 may not be limited thereto.

The upper transparent electrode 500 may be provided on the second electron/hole transport layer 330. The upper transparent electrode 500 may have a multilayer structure including a first color implementation layer 510, an intermediate layer 520, and a second color implementation layer 530, which are sequentially stacked. The upper transparent electrode 200 may have a thickness H3 of about 10 nm to about 100 nm. Electrons or holes generated by the photoelectric effect may flow through the upper transparent electrode 500.

The first color implementation layer 510 of the upper transparent electrode 500 may be substantially the same as the first color implementation layer 210 of the lower transparent electrode 200 described in FIG. 1. The intermediate layer 520 of the upper transparent electrode 500 may be substantially the same as the intermediate layer 220 of the lower transparent electrode 200 described in FIG. 1. The second color implementation layer 530 of the upper transparent electrode 500 may be substantially the same as the second color implementation layer 230 of the lower transparent electrode 200 described in FIG. 1.

According to an embodiment of the inventive concept, the upper transparent electrode 500 may be a multilayer including first and second color implementation layers 510 and 530 and an intermediate layer 520, and the lower transparent electrode 200 may be a single layer. The refractive index of the upper transparent electrode 500 may vary according to the amount of dopant impurities in the first and second color implementation layers 510 and 530, and brightness and chroma of solar light reflected from the upper transparent electrode 500 may vary according to the thickness and material type of the intermediate layer 520.

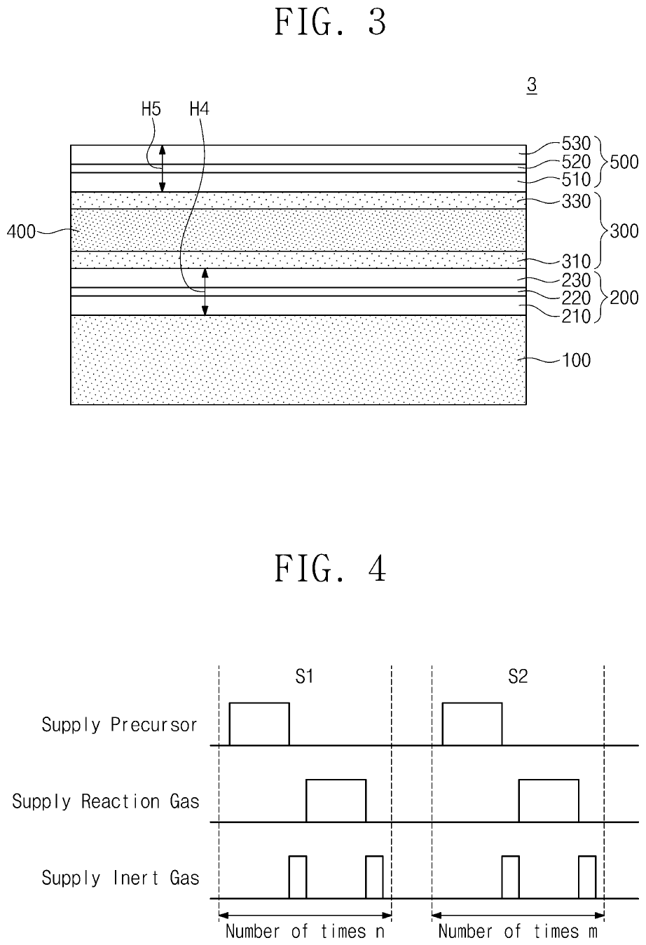

FIG. 3 is a cross-sectional view of a perovskite solar cell according to another embodiment of the inventive concept. Detailed descriptions of technical features that overlap those described with reference to FIGS. 1 and 2 will be omitted, and differences will be described in more detail.

Referring to FIG. 3, a perovskite solar cell 2 according to another embodiment of the inventive concept may include a substrate 100, a lower transparent electrode 200, an electron/hole transport layer 300, an absorption layer 400, and an upper transparent electrode 500. The substrate 100, the lower transparent electrode 200, the electron/hole transport layer 300, and the absorption layer 400 may be substantially the same as those described with reference to FIG. 1, and the upper transparent electrode 500 may be substantially the same as the upper transparent electrode 500 described with reference to FIG. 2. The lower transparent electrode 200 may have a thickness H4 of about 10 nm to about 200 nm, and the upper transparent electrode 500 may have a thickness H5 of about 10 nm to about 200 nm.

According to an embodiment of the inventive concept, the upper transparent electrode 500 may be a multilayer including first and second color implementation layers 510 and 530 and an intermediate layer 520, and the lower transparent electrode 200 may also be a multilayer including first and second color implementation layers 210 and 230 and an intermediate layer 220. The refractive index of the upper transparent electrode 500 may vary according to the amount of dopant impurities in the first and second color implementation layers 510 and 530 of the upper transparent electrode 500, and the refractive index of the lower transparent electrode 200 may vary according to the amount of dopant impurities in the first and second color implementation layers 210 and 230 of the lower transparent electrode 200. Refractive indices of each of the upper transparent electrode 500 and the lower transparent electrode 200 may be different from each other, and may be independently controlled. For example, brightness and chroma of solar light reflected from the upper transparent electrode 500 may be adjusted by varying the thickness and material type of the intermediate layer 520 of the upper transparent electrode 500, and brightness and chroma of solar light reflected from the lower transparent electrode 200 may be adjusted by varying the thickness and material type of the intermediate layer 220 of the lower transparent electrode 200. For another example, the brightness and chroma of reflected solar light may be adjusted by varying the thickness and refractive index of each of the second color implementation layer 230 of the lower transparent electrode 200 and the second color implementation layer 520 of the upper transparent electrode 500. For another example, the brightness and chroma of reflected solar light may be adjusted by varying the thickness and refractive index of each of the first color implementation layer 210 of the lower transparent electrode 200 and the first color implementation layer 510 of the upper transparent electrode 500. Light reflected from each of the upper transparent electrode 500 and the lower transparent electrode 200 interferes with each other, thereby providing a perovskite solar cell capable of displaying a wide range of colors.

Hereinafter, a method of manufacturing a perovskite solar cell according to an embodiment of the inventive concept will be described.

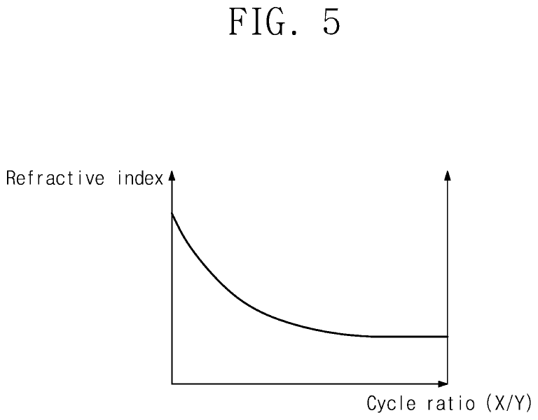

FIG. 4 is a conceptual view of a process for forming a first color implementation layer according to an embodiment of the inventive concept. FIG. 5 is a graph showing a change in refractive index of a lower transparent electrode according to an embodiment of the inventive concept. Hereinafter, FIGS. 4 and 5 will be described with reference to FIG. 1.

Referring back to FIG. 1, the lower transparent electrode 200 may be formed on the first surface 100a of the substrate 100. The forming of the lower transparent electrode 200 may include sequentially forming a first color implementation layer 210, an intermediate layer 220, and a second color implementation layer 230.

To be specific, the substrate 100 may be prepared in a chamber (not shown). The first color implementation layer 210 may be formed on the first surface 100a of the substrate 100. The forming of the first color implementation layer 210 may be performed through, for example, atomic layer deposition (ALD), but is not limited thereto. The forming of the first color implementation layer 210 may include, on the first surface 100a of the substrate 100, performing a first sub-cycle S1 n times and a second sub-cycle S2 m times.

More specifically, referring to FIG. 4, the performing of the first sub-cycle S1 may include supplying a first precursor into a chamber, supplying a first inert gas, supplying a first reaction gas, and resupplying the first inert gas. For example, the first reaction gas may be oxygen, sulfur, or nitrogen, and the first precursor may react with the first reaction gas to generate metal oxide, metal sulfide, or metal nitride. The first sub-cycle S1 may be performed n times in succession, and n above may be a natural number of about 1 to about 10.

After the first sub-cycle S1 is performed n times, the second sub-cycle S2 may be performed m times. The performing of the second sub-cycle S2 may include supplying a second precursor, supplying a second inert gas, supplying a second reaction gas, and resupplying the second inert gas. For example, the second reaction gas may be oxygen, sulfur, or nitrogen, and the second precursor may be different from the first precursor. The second precursor reacts with the second reaction gas, and the first color implementation layer 210 may thus be doped with impurities. The second sub-cycle S2 may be performed m times in succession, and m above may be a natural number of about 1 to about 100. Accordingly, the first color implementation layer 210 may be formed on the substrate 100.

The amount of impurities contained in the first color implementation layer 210 may be adjusted by repeating the second sub-cycle S2 a plurality of times. According to the amount of the impurities, the refractive index of the lower transparent electrode 200 may vary. Referring to FIG. 5, the refractive index of the lower transparent electrode 200 may vary according to a ratio (n/m) of the number of times (n) of performing the first sub-cycle S1 to the number of times (m) of performing the second sub-cycle S2. For example, the greater a ratio (n/m) of the number of times (n) of performing the first sub-cycle S1 to the number of times (m) of performing the second sub-cycle S2, the less a refractive index of the lower transparent electrode 200.

An intermediate layer 220 may be formed on the first color implementation layer 210. The forming of the intermediate layer 220 may include performing a sputtering type deposition process. More specifically, a metal material may be deposited on the first color implementation layer 210 to form the intermediate layer 220. The metal material may include silver (Ag), gold (Au), aluminum (Al), copper (Cu), titanium (Ti), platinum (Pt), tungsten (W), and/or nickel (Ni).

A second color implementation layer 230 may be formed on the intermediate layer 220. The forming of the second color implementation layer 230 may be the same as that of the first color implementation layer 210. More specifically, the first sub-cycle may be performed x times and the second sub-cycle may be performed y times. In this case, n above may be different from x, and m above may be different from y, but n and m above are not limited thereto.

A first electron/hole transport layer 310, a light absorption layer 400, and a second electron/hole transport layer 330 may be sequentially formed on the second color implementation layer 230. Each of the first electron/hole transport layer 310, the light absorption layer 400, and the second electron/hole transport layer 330 may be formed through vacuum deposition such as sputtering or evaporation or a wet process method.

An upper transparent electrode 500 may be formed on the second electron/hole transport layer 330. According to an embodiment, the upper transparent electrode 500 may be formed through vacuum deposition such as sputtering or evaporation. According to another embodiment, the upper transparent electrode 500 may be formed in the same manner as the lower transparent electrode 200. For example, the method may include, on the light absorption layer 400, sequentially forming a first color implementation layer 510, an intermediate layer 520, and a second color implementation layer 530. The forming of the first color implementation layer 510 may include, on the light absorption layer 400, performing the first sub-cycle a times and the second sub-cycle b times. In this case, a above may be different from x and n above, and b above may be different from y and m above, but a and b above are not limited thereto. The forming of the second color implementation layer 530 may include, on the light absorption layer 400, performing the first sub-cycle c times and the second sub-cycle d times. In this case, c above may be different from a above, and d above may be different from b above, but c and d above are not limited thereto. Accordingly, a perovskite solar cell according to an embodiment may be manufactured.

In the forming of the first color implementation layer 210 and the second color implementation layer 230, the number of times (n) in which the first sub-cycle S1 is performed and the number of times (m) in which the second sub-cycle S2 is performed may be adjusted to control the refractive index of the lower transparent electrode 200.

A perovskite solar cell according to embodiments of the inventive concept may include a transparent electrode including a first color implementation layer, an intermediate layer, and a second color implementation layer, which are sequentially stacked. Refractive indexes of each of the first color implementation layer and the second color implementation layer may be controlled by adjusting the amount of dopant impurities contained in the first color implementation layer and the second color implementation layer. In addition, brightness and chroma of solar light reflected from a solar cell may be controlled by adjusting the thickness and material of an intermediate layer. Accordingly, a solar cell capable of displaying a wide range of colors may be provided.

Effects of the present disclosure are not limited to the effects described above, and those skilled in the art may understand other effects from the following description.

Although the embodiments of the inventive concept have been described above with reference to the accompanying drawings, it will be understood by those skilled in the art to which the inventive concept pertains that the inventive concept may be implemented in other specific forms without changing the technical idea or essential features thereof. Therefore, it should be understood that the embodiments described above are presented as examples in all respects and not restrictive.

What is claimed is:

1. A perovskite solar cell comprising:
a substrate;
a lower transparent electrode provided on the substrate;
an upper transparent electrode provided on the lower transparent electrode; and
a light absorption layer interposed between the lower transparent electrode and the upper transparent electrode;
wherein the light absorption layer includes a perovskite material, and
at least one of the lower transparent electrode or the upper transparent electrode includes a first color implementation layer, an intermediate layer, and a second color implementation layer, which are sequentially stacked,
the first color implementation layer and the second color implementation layer each being a metal oxide layer containing a dopant.

2. The perovskite solar cell of claim 1, wherein the intermediate layer contains silver (Ag), gold (Au), aluminum (Al), copper (Cu), titanium (Ti), platinum (Pt), tungsten (W), nickel (Ni), and/or titanium nitride (TiN).

3. The perovskite solar cell of claim 1, wherein the dopant contains boron (B), aluminum (Al), gallium (Ga), indium (In), a lanthanide element, and/or titanium (Ti).

4. The perovskite solar cell of claim 1, wherein the metal oxide contains ZnO, TiO₂, SnO₂, In₂O₃, ITO, ATO (antimony tin oxide), WO_{N}, and/or MoOₓ.

5. The perovskite solar cell of claim 1, wherein the intermediate layer has a thickness of about 1 nm to about 15 nm.

6. The perovskite solar cell of claim 1, wherein the lower transparent electrode and the upper transparent electrode each have a thickness of about 10 nm to about 200 nm.

7. The perovskite solar cell of claim 1, wherein the light absorption layer is opaque.

8. The perovskite solar cell of claim 1, wherein the first color implementation layer has the same refractive index as the second color implementation layer.

9. A method of manufacturing a perovskite solar cell, the method comprising:
forming a lower transparent electrode on a substrate; and
forming a light absorption layer on the lower transparent electrode,
wherein the forming of the lower transparent electrode includes sequentially forming a first color implementation layer, an intermediate layer, and a second color implementation layer on the substrate, and
the forming of the first color implementation layer includes performing a first sub-cycle n times and performing a second sub-cycle m times,
the first sub-cycle including:
supplying a first precursor into a chamber in which the substrate is prepared;
supplying a first inert gas into the chamber to perform a first purge process;
supplying a first reaction gas into the chamber; and
supplying a second inert gas into the chamber to perform a second purge process.

10. The method of claim 9, wherein:
n above is a natural number of 1 to 10; and
m above is a natural number of 1 to 100.

11. The method of claim 9, wherein the second sub-cycle comprises:
supplying a second precursor into the chamber;
supplying a third inert gas into the chamber to perform a third purge process;
supplying a second reaction gas into the chamber; and
supplying a fourth inert gas into the chamber to perform a fourth purge process;
the second precursor containing a different material from the first precursor.

12. The method of claim 9, wherein the first color implementation layer and the second color implementation layer each are a metal oxide layer containing a dopant, and
the intermediate layer contains silver (Ag), gold (Au), aluminum (Al), copper (Cu), titanium (Ti), platinum (Pt), tungsten (W), nickel (Ni), and/or titanium nitride (TiN).

13. The method of claim 9, wherein the light absorption layer comprises a perovskite material.

14. The method of claim 9, wherein the forming of the second color implementation layer comprises, on the intermediate layer, performing the first sub-cycle x times and performing the second sub-cycle y times,
n above being different from x above, and m above being different from y above.

15. The method of claim 14, further comprising forming an upper transparent electrode on the light absorption layer,
wherein the forming of the upper transparent electrode includes, on the light absorption layer, sequentially forming a third color implementation layer, an intermediate layer, and a fourth color implementation layer,
the forming of the third color implementation layer including, on the light absorption layer, performing the first sub-cycle a times and the second sub-cycle b times.

16. The method of claim 15, wherein the forming of the fourth color implementation layer comprises, on the intermediate layer, performing the first sub-cycle c times and performing the second sub-cycle d times,
a above being different from c above, and b above being different from d above.

17. The method of claim 9, wherein the greater a ratio of the number of times n of performing the first sub-cycle to the number of times m of performing the second sub-cycle, the less a refractive index of the lower transparent electrode.
